(19) United States
(12) Patent Application Publication
(10) Pub. No.: US 2009/0000662 A1
(43) Pub. Date: Jan. 1, 2009

(54) Photovoltaic receiver for solar concentrator applications

(76) Inventors: Duncan W.J. Harwood, Santa Clara, CA (US); Tyler K. Williams, San Francisco, CA (US); David T. Youmans, Berkeley, CA (US)

Correspondence Address: KAGAN BINDER, PLLC, SUITE 200, MAPLE ISLAND BUILDING, 221 MAIN STREET NORTH, STILLWATER, MN, 55082, US

(21) Appl. No.: 12/075,147

(22) Filed: Mar. 10, 2008

Related U.S. Application Data
(60) Provisional application No. 60/906,383, filed on Mar. 11, 2007.

(51) Int. Cl. H01L 31/00; B29C 45/14

(52) U.S. Cl. 136/259; 156/288

(57) ABSTRACT

The present invention provides solar concentrators incorporating photovoltaic receiver assemblies with improved thermal dissipation, dielectric, encapsulation, and cell/wiring protection characteristics. The concentrators are particularly useful for photovoltaic power systems such as rooftop mounted systems. The present invention teaches that the geometry of the substrate used to support receiver assemblies can have a dramatic impact upon thermal/dielectric performance. In particular, the present invention teaches how contours incorporated into such substrates can improve thermal performance (i.e., dissipation of thermal energy from photovoltaic cells through the substrate) while still maintaining dielectric and encapsulation objectives. In the past, dielectric and encapsulation objectives have been obtained at the expense of such thermal dissipation. Also, material choice and form also impacts thermal, dielectric, and encapsulation performance. In preferred embodiments, components of receiver assemblies are provided in sheet form and laminated together in the course of making the receiver assemblies.

### PRIORITY CLAIM

The present non-provisional patent Application claims priority under 35 USC §119(e) from U.S. Provisional Patent Application having Ser. No. 60/906383, filed on Mar. 11, 2007, by Harwood et al., and titled PHOTOVOLTAIC RECEIVER FOR SOLAR CONCENTRATOR APPLICATIONS, wherein the entirety of said provisional patent application is incorporated herein by reference.

### FIELD OF THE INVENTION

The present invention relates to solar concentrator modules that concentrate incident light onto photovoltaic receivers. More particularly, the present invention relates to such solar concentrators incorporating photovoltaic receivers with improved thermal dissipation, dielectric, encapsulation, and protection characteristics.

### BACKGROUND OF THE INVENTION

Optical concentrating systems, such as solar collectors, concentrate light toward a focus of the optical system. A photovoltaic receiver assembly captures the concentrated light and converts it into electrical energy. In general, there are two categories of concentrators. Line concentrators concentrate incident light in one dimension so that the focus is a line. Point concentrators concentrate incident light in two dimensions so that the focus is a point.

Concentrators may include one or more optical components to concentrate incident light. Some systems have a single concentrating optical component, referred to as the primary optic, that concentrates rays directly onto the desired target (which may be a device such as a photovoltaic cell) after being collected and focused by the optic. More complex concentrators may include both a primary optic and additional optics to provide further collection or concentration abilities or improve beam uniformity at the target.

At low concentration ratios, the receiver assembly in a concentrator module of a concentrating photovoltaic panel (CPV) can share many of the characteristics of conventional flat panel technology. However, the increased intensity at the cell requires improved thermal management to maximize power output, yet must still maintain the dielectric standoff needed to meet the safety requirements of UL1703. Thus, photovoltaic power systems, such as rooftop concentrator modules, desirably involve receiver assemblies that satisfy the requirements of good thermal dissipation and dielectric standoff. Conventional structures for receiver assemblies are described in Handbook of Photovoltaic Science and Engineering, A. Luque and S. Hegedus, 2005. Such structures have included thick layers of EVA (ethylene vinyl acetate) and usually a thick layer of PVF (available under the trade designation TEDLAR) or PVF/PET laminates. However, to meet the thermal requirements of a concentrating module, new materials or combinations of materials are needed for better thermal dissipation, dielectric standoff, encapsulation reliability, and the like.

### SUMMARY OF THE INVENTION

The present invention provides solar concentrators incorporating photovoltaic receiver assemblies with improved thermal dissipation, dielectric, encapsulation, and cell/wiring protection characteristics. The concentrators are particularly useful for photovoltaic power systems such as rooftop mounted systems. The present invention teaches that the geometry of the substrate used to support receiver assemblies can have a dramatic impact upon thermal/dielectric performance. In particular, the present invention teaches how contours incorporated into such substrates can improve thermal performance (i.e., dissipation of thermal energy from photovoltaic cells through the substrate) while still maintaining dielectric and encapsulation objectives. In the past, dielectric and encapsulation objectives have been obtained at the expense of such thermal dissipation. Also, material choice and form also impacts thermal, dielectric, and encapsulation performance. In preferred embodiments, components of receiver assemblies are provided in sheet form and laminated together in the course of making the receiver assemblies.

In one aspect, the present invention relates to a photovoltaic concentrator module. The module comprises a photovoltaic receiver assembly and an optic that concentrates incident light onto the receiver assembly. The photovoltaic receiver assembly comprises at least one wired photovoltaic cell supported upon and thermally coupled to a thermally conductive substrate. The wired photovoltaic cell comprises a wiring interconnection electrically coupled to the cell. The receiver assembly comprises a dielectric layer interposed between the at least one wired photovoltaic cell and the substrate to help electrically isolate the wired photovoltaic cell from the substrate. The substrate comprises a contour underlying the wiring interconnection.

In another aspect, the present invention relates to a photovoltaic receiver. The photovoltaic receiver comprises at least one wired photovoltaic cell supported upon and thermally coupled to a thermally conductive substrate. The wired photovoltaic cell comprises a photovoltaic cell and a wire interconnection electrically coupled to the cell. The receiver comprises a dielectric layer interposed between the at least one wired photovoltaic cell and the substrate to help electrically isolate the wired photovoltaic cell from the substrate. The substrate comprises a contour underlying the wired interconnection.

In another aspect, the present invention relates to a method of making a photovoltaic receiver assembly, comprising the steps of:
a) providing a jig base having first and second faces;
b) providing a pin carrier comprising a plurality of alignment pins projecting from a face of the pin carrier;
c) causing the pin carrier to be positioned against the first face of the jig base so that the alignment pins project through corresponding holes of the jig base to project from the second face of the jig base;
d) positioning a first component of the photovoltaic receiver assembly against the second face of the jig base using the alignment pins to aid positioning;
e) clamping the first component to the second face of the jig base;
f) removing the pin carrier from the jig base;
g) positioning a second component of the photovoltaic receiver assembly against the first face of the jig base, wherein at least one of the first and second components is thermoformable; and
h) while the first and second components are held in the jig base, causing the components of the photovoltaic receiver assembly to be laminated together.

In another aspect the present invention relates to a method of making a photovoltaic receiver assembly, comprising the steps of:
a) providing a jig base having first and second faces;
b) positioning a first component of the photovoltaic receiver assembly against the second face of the jig base using a plurality of alignment features to aid positioning;
c) clamping the first component to the second face of the jig base;
d) positioning a second component of the photovoltaic receiver assembly against the first face of the jig base, wherein at least one of the first and second components is thermoformable; and
e) while the first and second components are held in the jig base, causing the components of the photovoltaic receiver assembly to be laminated together.

In another aspect, the present invention relates to a method of making a photovoltaic receiver assembly, comprising the steps of:
a) arranging a plurality of components of the photovoltaic receiver assembly in a stack;
b) positioning a spacer adjacent a side of the stack; and
c) applying a laminating pressure to the stack and the spacer.

The following co-pending applications of the present Assignee describe solar concentrator modules and photovoltaic power systems incorporating such modules: U.S. Patent Publication Nos. 2006/0283497, 2007/0102037, 2007/0089777, 2007/0193620; and 2007/0188876. The receiver described herein may be used in any such module or system. The respective entirety of each of these co-pending applications is incorporated herein by reference for all purposes.

### BRIEF DESCRIPTION OF THE DRAWINGS

The above mentioned and other advantages of the present invention, and the manner of attaining them, will become more apparent and the invention itself will be better understood by reference to the following description of the embodiments of the invention taken in conjunction with the accompanying drawings, wherein:

FIG. 1 is a cross section view of a solar concentrator module of the present invention.

FIG. 2 is a perspective view of the solar concentrator module of FIG. 1.

FIG. 3 is a cross section view showing optical pathways for diffuse light in the solar concentrator module of FIG. 1.

FIG. 4 is an exploded perspective view of a receiver assembly used in the solar concentrator module of FIG. 1.

FIG. 5 is an end, schematic cross-section view of an alternative embodiment of a solar concentrator module including a thick, lower dielectric layer.

FIG. 6 is an end, schematic cross-section view of an alternative embodiment of a solar concentrator module including a thin, lower dielectric layer.

FIG. 7 is an end, schematic cross-section view of an alternative embodiment of a solar concentrator module including a thin, lower dielectric layer and a contoured substrate.

FIG. 8 is an end, schematic cross-section view of an alternative embodiment of a solar concentrator module including a thick, lower dielectric layer and a contoured substrate.

FIG. 9 is a perspective view of a portion of a jig useful in the stringing, lay-up, and lamination of receiver assemblies of the present invention, wherein the view shows a jig base supported on a pin carrier with tabbed cells being placed into position on the base with the aid of alignment pins supported on the pin carrier.

FIG. 10 is a close-up perspective view of the jig of FIG. 9 showing a tabbed cell placed into position with the aid of alignment pins and a recess in the face of the jig base, and diodes being placed into position with the aid of diode pockets in the base.

FIG. 11 is a perspective view of the jig of FIG. 9 showing placement of a substrate preassembly onto the jig, wherein the preassembly includes a dielectric film pre-laminated to a substrate.

FIG. 12 shows a close-up perspective view of a portion of the jig of FIG. 9 in which a clamping board has been placed in position over the base to help hold components in position.

FIG. 13 shows a perspective view of the jig of FIG. 9 in which the clamping board is clamped to the base and the pin carrier has been withdrawn from the base.

FIG. 14 shows a perspective view of the clamping board and base assembly shown in FIG. 13 in which the assembly has been flipped over to allow placement of an upper encapsulating layer and a cover onto the jig in proper position over the other components of the receiver assembly already laid up in position on the jig.

FIG. 15 is a schematic illustration of forces acting on a receiver assembly when a lamination bladder is used for lamination, wherein these forces can impact ribbon shifting during lamination.

FIG. 16 is a schematic illustration showing how using spacers shorter in height than the receiver assembly can modulate the bladder forces acting on a receiver assembly that cause ribbon shifting.

FIG. 17 is a schematic illustration showing how using spacers that are the same height as the receiver assembly can modulate the bladder forces acting on a receiver assembly that cause ribbon shifting.

FIG. 18 is a schematic illustration showing how using spacers taller in height than the receiver assembly can modulate the bladder forces acting on a receiver assembly that cause ribbon shifting.

FIG. 19 schematically illustrates an overview of a test sequence for evaluating the performance of receiver assemblies.

FIG. 20 is a graph comparing fill factor performance versus environmental stressor for receiver assemblies that include flat substrates and substrates contoured with rectangular grooves, respectively.

FIG. 21 is a graph comparing fill factor performance versus environmental stressor for receiver assemblies that include substrates contoured with trapezoidal grooves with rounded transitions.

FIG. 22 is a graph comparing fill factor performance versus environmental stressor for receiver assemblies that include different lower dielectric layers.

### DETAILED DESCRIPTION OF PRESENTLY PREFERRED EMBODIMENTS

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention.

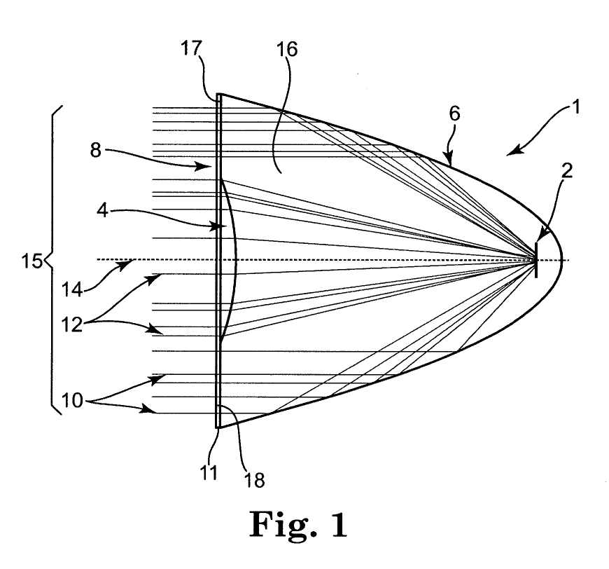

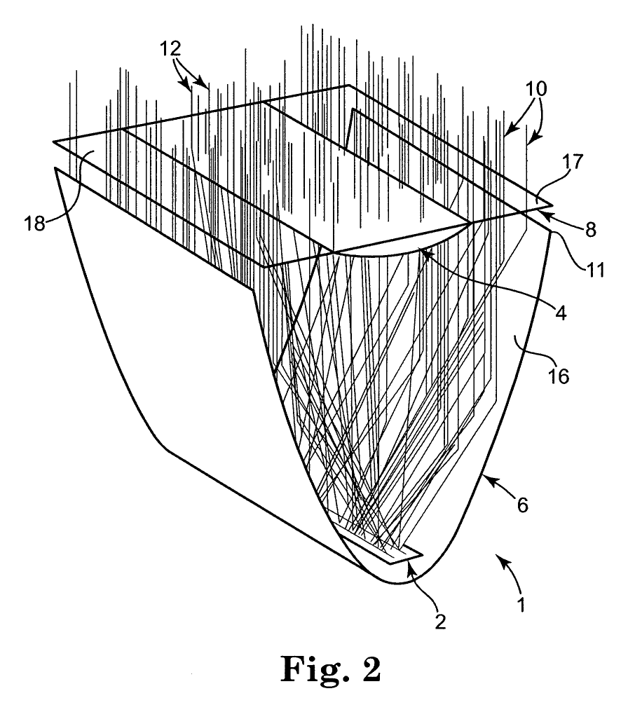

FIGS. 1 through 3 show one preferred embodiment of a photovoltaic concentrator module 1 of this invention. For purposes of illustration photovoltaic concentrator module 1 is in the form of a linear concentrating trough module design such as is used in the HELIOTUBE™ photovoltaic power system developed by Soliant Energy, Inc., Pasadena, Calif. (formerly Practical Instruments, Inc.). However, the principles of the present invention are useful in any solar concentrating application in which an optic element concentrates incident light onto a photovoltaic cell. The full aperture 15 of module 1 spans the width (in the case of a line concentrator) or diameter (in the case of a point concentrator) of the light-receiving end 11 of a reflective element in the form of a bottom-focusing dish 6. The module 1 includes a cover 8 fitted onto light-receiving end 11. Together, the cover 8 and dish 6 provide a protective housing for device components housed in the interior 16.

The reflective surface of dish 6 of the preferred embodiment is nearly parabolic in shape. However, the reflecting element, as an alternative, can use any appropriate reflecting surface including but not limited to surfaces having linear, parabolic, faceted, spherical, elliptical, or hyperbolic profiles.

The cover 8 includes a refractive element in the form of integral plano-convex lens 4 in a central region of cover 8 and transparent, light transmissive outer regions 17 and 18. The lens 4 and dish 6 share a common focus and a common optical axis 14 and concentrate incident light onto receiver assembly 2. Lens 4 is positioned so that lens 4 is centered about the optical axis 14 of the module 1. The nearly parabolic reflector dish 6 also is centered about the optical axis 14 of the system.

Lens 4 may be of any suitable type including Fresnel and standard types. Even though Fresnel lenses tend to be expensive and lossy, Fresnel lenses are commonly used because a standard lens of the required diameter would be too thick and would use too much expensive and/or heavy optical material. In contrast, the refractive element of the present invention provides concentration for only a fraction of the system aperture 15, thereby allowing a smaller-diameter and thus much thinner lens for the same concentration ratio, as compared to a much thicker, full-aperture lens. As such, the present invention may alternatively employ a standard lens for a range of system apertures that would traditionally require a Fresnel lens. For purposes of illustration, lens 4 is shown as a standard lens.

The optics of module 1 are hybrid in that reflective and refractive optical elements, e.g., lens 4 and dish 6 in this embodiment, respectively serve as a primary optic for respective portions of the collecting aperture 15. In use, incident rays 12 that are incident upon the central portion of the collecting aperture 15 pass through lens 4 of cover 8 and are thereby refractively focused by lens 4 onto the common focal plane 2. In the meantime, incident rays 10 that are incident upon the outer portions 17 and 18 of the collecting aperture 15 pass through cover 8 and are focused by the reflecting dish 6 onto the common focal plane 2. In other words, incident rays 12 are concentrated by lens 4 and not by the dish 6, while incident rays 10 are concentrated by the dish 6 and not by the lens 4. This differentiates module 1 from and improves upon multi-stage concentrators that incorporate refractive and reflective components only in series. Concentrator modules including hybrid optics are further described in Assignee's co-pending United States Patent Publication No. 2007/0188876.

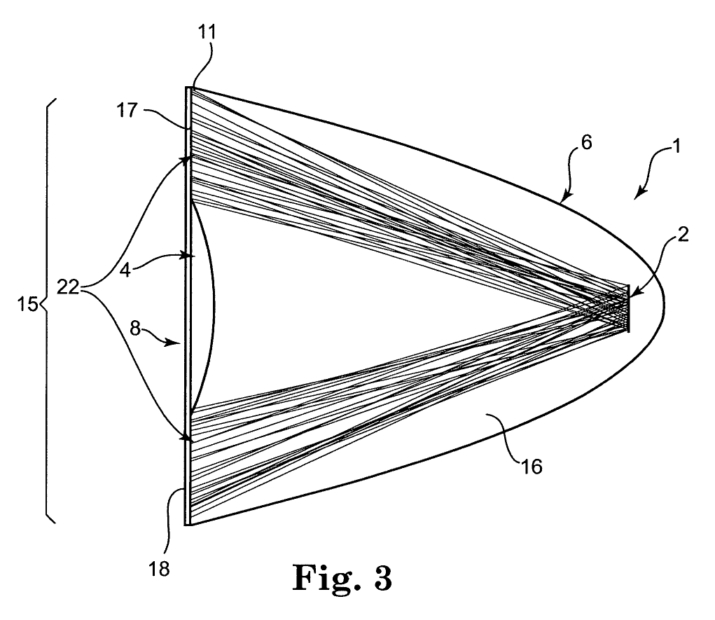

Hybrid optics are very compatible for use with self-powered, articulating optical concentrators, because the present invention provides sufficient paths for diffuse radiation to reach the receiver assembly 2. This is best seen in FIG. 3. Because the total aperture 15 of the hybrid optical component of the present invention is larger than the lens aperture, there exist optical paths not parallel to the optical axis 14, through the cover element 8, that neither strike the refractive element 4 nor the reflective dish 6. These optical paths allow diffuse radiation 22 to be directly absorbed by a solar cell located at the receiver assembly 2. This helps an articulating optical concentrator that includes the hybrid optical component to generate sufficient self-power to articulate itself even when not pointed at the sun. In contrast, inasmuch as full aperture Fresnel refractors typically allow only a small amount of diffuse light to reach the focal plane, full aperture Fresnel-refractor systems are generally not well suited to self-powering.

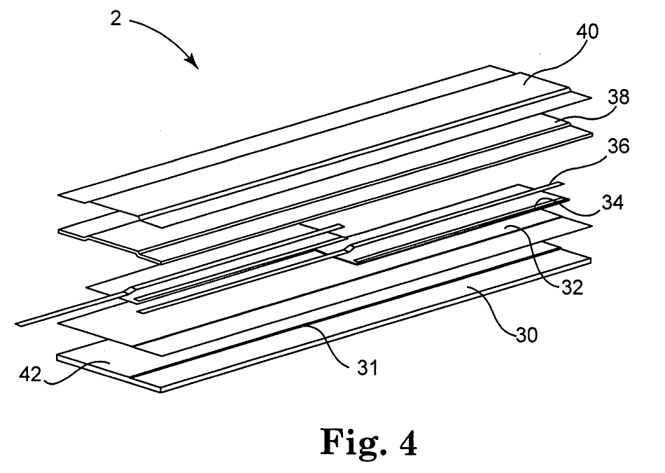

The receiver assembly 2 of the present invention may have a variety of configurations. An illustrative configuration of the receiver assembly 2 is shown in more detail in FIG. 4. There, receiver assembly 2 includes substrate 30, lower encapsulant/dielectric layer 32, at least one photovoltaic cell 34, ribbon wire interconnections 36, upper encapsulant layer 38, and cover 40.

A main purpose of substrate 30 is to spread absorbed heat over a larger area to minimize thermal resistance between the cells 34 and the carrier/trough bond line. Additionally, the substrate 30 also functions as a carrier that assists in handling and bonding of receiver assembly 2 to its appropriate location, preferably the dish 6. Substrate 30 preferably comprises aluminum, which is a material that performs both the thermal and support functions.

The simplest substrate design is a thin, flat strip. For purposes of illustration, however, substrate 30 is shown with a scoring line 31 along its length, schematically illustrating a contour in the form of a groove along the length of the substrate that underlies a ribbon wire interconnection. As the lower encapsulating/dielectric layer 32 becomes thin (approaching the thickness of the interconnecting ribbon wire interconnections 36), the present invention appreciates that there is an increasing motivation to contour the upper face 42 of the substrate 30 to accommodate the profile of the cell and ribbon wire when present. When the substrate 30 includes a contour 31 that corresponds to the profile of the cell and ribbon wire in this fashion, at least a portion of the cell or wire can fit into the pocket formed by the contour 31. Consequently, a contoured substrate 30 decreases the thermal impedance between substrate 30 and the cells 34. For example, a contoured substrate 30 also allows the lower encapsulating/dielectric layer 32 to be much thinner to increase thermal transfer to the substrate 30 while still electrically insulating the cell wiring interconnections 36 from the underlying substrate 30. A contoured geometry also reduces the chance of cell damage or breakage, especially during lamination when significant downward force is applied to the entire receiver assembly 2.

Such a contour can have a variety of geometries. Contours can include portions that are linear, arcuate, or a piece-wise continuous profile of any function. For instance, a square shaped groove can be used. Alternatively, contours can include arcuate portions, optionally with changing radii of curvature. As another example, a contour may include first and second planes wherein the transition between the two planes is rounded to avoid a line of intersection between the two planes. An example of such a groove is one with a trapezoidal cross-section with one or more corners of the profile being generally rounded. Experiments are described below in which two groove configurations were evaluated: a square sided groove (GRV-1) and a trapezoidal groove with rounded corners (GRV-2). The square-sided groove had a width of 0.099+/−0.003 inches and a depth of 0.025 inches. The top edges were beveled at 45 degrees to provide facets having widths of 0.005 inches. The bottom corners were square. The trapezoidal groove had a width of 0.097+/−0.001 inches across the top. The sides tapered downward and inward to the bottom of the groove at 135 degrees to a depth of 0.0044+/−0.0005 inches. The top and bottom edges of the grooves were rounded with a radius of 0.006 inches. The experiments showed that both grooves enhance heat dissipation, but that the trapezoidal groove has a smoother profile to minimize stresses during lamination when lamination techniques are used to fabricate a receiver assembly.

When the contour has a profile that will correspond to a portion of a wire 36 that might be underlying cells 34, the contour has a width and depth sufficient for a wire portion to fit into the contour with enough space around the wire to allow dielectric material in layer 32 to be of sufficient thickness to establish electric isolation between the cells 34 and wire 36 on the one hand and the substrate 30 on the other.

The lower encapsulant/dielectric layer 32 is interposed between the substrate 30 and the overlying cells 34 and serves three functions. First, the material contributes to complete encapsulation of the cells 34 for environmental stability. The material also electrically isolates the cells 34 from the substrate 30. Additionally, the material provides a path of low thermal resistance between the cells and the substrate to help dissipate heat. As the thickness of layer 32 increases, it becomes easier to satisfy encapsulation and electrical isolation. The thermal resistance requirement, on the other hand, makes it desirable for layer 32 to be as thin as possible. Accordingly, the present invention provides strategies that allow all three objectives to be achieved.

According to one strategy, the layer 32 is made from porous materials with a dielectric standoff, such as fiberglass or glass beads, through which an encapsulant precursor, also with sufficient dielectric standoff, can be caused to flow and then cure. In this strategy, the dielectric requirements and encapsulation on the corresponding side of the cells and wiring are accomplished simultaneously. One example of a fiberglass-impregnated material is fiberglass-impregnated silicone. Such a material is available from The Bergquist Company, Chanhassen, Minn., under the trade designation Bond Ply LMS. This product is an uncured sheet form in which “green” silicone impregnates a single layer 0/90 fiberglass weave. It has been used for bonding power electronics to heat sinks. It combines many attractive features, such as minimal total thickness (6.5 mils) and high thermal conductivity (1.5 W/m K). Another example is Fiberglass-impregnated EVA (ethylene vinyl acetate) provided with a fiberglass “scrim” on one or both sides to help promote the escape of trapped air. In one experiment, the material provided was from STR (Specialized Technology Resources, Inc.) and the scrim appeared to be a randomly oriented chopped fiber layer. While only easily available in a relatively thick layer (18 mils), this material has been used as a dielectric in other commercial applications including aluminum substrates.

According to another strategy for forming encapsulant/dielectric layer 32, the substrate surface can be treated directly such as by coating with a fluid layer, which is then cured. The cells and wiring are positioned over this cured coating, and then encapsulation is subsequently completed via a subsequent, further encapsulation step. One such treatment may involve a powdercoat. When the substrate is aluminum, these may be used with or without pre-anodization of the substrate. Powdercoat material has similar thermal and dielectric performance to polyester, but is easier to apply. An example of such a material is an outdoor-rated polyester-based powder coat available from Tiger Drylac available under the trade designation Series 49, color REL 9016, normally used for architectural finishes. There may be possible concerns with pinholes and dielectric consistency with respect to using powdercoat material.

As an alternative to a powder coating approach, liquid coatings may be used. One example is a polyurethane-based liquid coating available under the trade designation Polane-S from Sherwin Williams. It may be applied over an anodizing pretreatment on an aluminum substrate. This polyurethane material is recommended by surface finishing vendors for aluminum. A high performance aluminum Oxide Epoxy coating may also be used. An example is a thermally conductive epoxy with aluminum oxide filler from Castall. The resin investigated is identified by the 343 A/B designation.

More preferably, a solid sheet of a dielectric material is bonded to the substrate 30 to form the encapsulant/dielectric layer 32. The cells and wiring are positioned over the laminated sheet, and then encapsulation is subsequently completed via a subsequent, further encapsulation film. Laminating a sheet of dielectric material is possibly the most process-intensive method of applying a dielectric layer, but also promises to be the most reliable. This method also has a history of use in other concentrating modules. The pressures and temperatures required for lamination of sheet materials to a substrate require a pre-processing lamination step separate from the receiver encapsulation lamination step.

In representative embodiments involving contoured substrates, illustrative layers 32 are derived from films having a thickness of less than about 1 mm, preferably less than about 0.03 mm (0.0012 inches). In one embodiment, a film having a thickness of 1 mil (0.001 inches or 0.025 mm) would be suitable. In other embodiments, the thickness of the dielectric film used to form the layer 32 is in the range from about 0.0055 inches (0.14 mm) to about 0.008 inches (0.20 mm).

Polyester (PET) film is an example of a suitable dielectric sheet material. For example, polyester, sold under trade designations such as MELINEX or MYLAR, is a standard material for dielectric standoffs in conventional flat plate modules. However, normal polyester formulations will not adhere directly to aluminum. Two materials from Dupont Teijin were identified that have a thermally activated adhesive on one side that is designed for adhesion to aluminum. In addition, these materials (MELINEX 301H and MYLAR OL13) were available in a 1 mil thickness, which lent them attractive thermal properties and sufficient dielectric strength. In addition to PET, PVF sheets may also be used. PVF, sold under the trade name of TEDLAR, is another standard material for photovoltaic backsheets and possesses similar dielectric and thermal properties to PET. The DuPont document titled “Adhesive and Lamination Guide for TEDLAR® PVF Film” explains how to achieve lamination using the TEDLAR sheets. This document explains that “Lamination is accomplished by cleaning the metal, depositing a controlled conversion coating on the metal, coating the metal with a solvent-based adhesive, evaporating the solvent, heating the metal to 195° C.-205° C. (383° F.-401° F.) to activate the adhesive, combining with TEDLAR® PVF film in nip rolls and quenching the laminate.” The “solvent-based adhesive” referred to in the document is DuPont adhesives 68070, 68065. Of the solid sheet materials tested, the MELINEX 301H offered the best combination of thermal performance and adhesion to aluminum. However, a film of EVA, such as an 8 mil thick film available from STR, may be incorporated into the lower encapsulant/dielectric layer 32 to ensure complete encapsulation.

Multilayer laminates also may be used. An example is a three-layer laminate of EVA/PET/EVA (hereafter referred to as “EPE laminate”), sold as PHOTOMARK EPE from Madico. Initially it appeared very attractive due to the two layers of EVA which could potentially bond to an aluminum substrate on one side and encapsulate the cells on the other in those embodiments including an aluminum substrate. However, the particular formulation of EVA used in this product does neither of those things without additional processing and is mainly used as a primer to bond to other layers of EVA. In order to bond the EPE laminate to aluminum, the aluminum desirably is pretreated with DuPont adhesives 68070 or 68065, similar to the bonding process for PVF film. In addition, the laminate has a 10 mil total thickness, making it a less attractive option compared with either a single, thinner layer of PET or PVF.

The following table lists exemplary materials useful to form encapsulant/dielectric layer 32:

| | | | | | Predicted | |
|---|---|---|---|---|---|---|
| | | | | | Dielectric | |
| | | | Thermal | | Strength | |
| Dielectric | Thickness | | Conductivity | | (V) | |
| Silicone with Fiberglass | 6.5 | mils | 5470 | W/m\hat{ }2 K | 3500 | AC |
| Bergquist Bond Ply LMS | | | | | | |
| EVA with Fiberglass | 18 | mils | 560 | W/m\hat{ }2 K | — | |
| Bergquist Bond Ply | | | | | | |
| LMS | | | | | | |
| Powder Coating | 5 | mil (w/ primer) | 1600 | W/m\hat{ }2 K | 3000 | |
| Tiger Drylac Series 49, | | | | | | |
| REL 9016 | | | | | | |
| Liquid Coating | 2-3 | mils | 3200 | W/m\hat{ }2 K | 2300 | |
| Polane-S Polyurethane | | | | | | |
| Aluminum Oxide | 4 | mils | ~11,000 | W/m\hat{ }2 K | 3000 | |
| Epoxy | | | | | | |
| Castall 343 A-B | | | | | | |
| PET film | 1 | mil | 6090 | W/m\hat{ }2 K | 8000 | |
| Dupont Tejien Mylar | | | | | | |
| OL13, | | | | | | |
| PET film | 0.8 | mil | 6090 | W/m\hat{ }2 K | 6400 | |
| Dupont Tejien Melinex | | | | | | |
| 301H | | | | | | |

| | | | | | |
|---|---|---|---|---|---|
| EVA/PET/EVA film | 10 | mil | ~1000 | W/m\hat{ }2 K | — |
| Madico EPE | | | | | |
| PVF film | 2-5 | mil, TBD | ~2500-1000 | W/m\hat{ }2 K | — |
| Dupont Tedlar | | | | | |

Receiver assembly 2 preferably includes a plurality of photovoltaic cells 34, preferably placed end-to-end along the length of the receiver assembly 2. Photovoltaic cells 34 can be wired electrically either in series or parallel with each other. Ribbon wires 36 provide these electrical interconnections in the illustrated embodiment. Representative ribbon wires may have a thickness in the range of 0.006 inches to about 0.008 inches. Preferred ribbon wires 36 are solder-coated copper ribbon wire. Optionally, receiver assembly 2 can be wired with other concentrating modules (not shown) such as in series to produce a high voltage for an entire array system (not shown) that approaches the limits allowed by applicable electrical codes.

In preferred embodiments, cells 34 are high-efficiency silicon cells or the like, e.g., high efficiency solar cells commercially available from Sunpower Corp. or Q-cells AG. Such preferred cells 34 can be used in receiver assembly 2 and possibly wired together with other concentrating modules (not shown) in order to achieve a power output which may exceed 130 watts peak, which is commensurate with the output of some flat photovoltaic panels of similar size on the market today. However, alternative embodiments may use any cells that are suitable, including other high-efficiency and/or low-cost cells. In the preferred line focus concentrator module (such as HELIOTUBE), solar cells 34 are preferably narrower in width than standard solar cells.

An exemplary receiver assembly as used in the HELIOTUBE concentrator module may include 14 cells per module. In practice, receivers may have more or less cells than this as desired. For example, sample modules tested below involved experiments with a receiver embodiment having four cells.

Receiver assembly 2 will tend to heat due to the sunlight concentrated onto it at the base of the dish 6. Since the photovoltaic cells 34 tend to operate less efficiently at high temperature, it is preferable to cool the cells 34 so as to maintain receiver assembly 2 at a desirable functioning temperature. Preferably, cells 34 are thermally coupled to substrate 30 and dish 6 in turn is thermally coupled to the substrate 30 to help dissipate the heat and passively cool receiver assembly 2. Advantageously, in embodiments in which dish 6 is formed from a material such as aluminum, sufficient passive cooling is provided by the dish 6 to keep the cells 34 within a desirable temperature range.

Receiver assembly 2 also preferably includes one or more bypass diodes (not shown). Bypass diodes are generally desirable to protect the solar cells 34 from harmful voltages. The present invention teaches that it may be desirable to incorporate diodes into the receiver assembly 2. Depending on details of the solar cells used, an embodiment may include one bypass diode per concentrator module 1, or several concentrator modules may share diodes, or one bypass diode may be used for the entire concentrating solar panel, or there may be several bypass diodes per receiver assembly 2. The bypass diodes may be part of the module 1 or they may be external to the module 1. The preferred embodiment has one bypass diode per every few cells 34, resulting in there being several bypass diodes included in each receiver assembly 2.

The upper encapsulant layer 38 overlies the cells 34 and wiring interconnections 36. Together, the lower encapsulant/dielectric layer 32 and the upper encapsulant layer 38 completely encapsulate the cells 34 and wiring 36 for environmental stability. In addition, the upper encapsulant layer 38 and cover 40 provide a protective cover over the cells and wiring to protect them from environmental exposure. In addition to withstanding environmental exposure over a 20-year period, the receiver assembly 2 should also be able to satisfy the cut and push test requirements of UL 1703.

As shown in FIG. 4, upper encapsulant layer 38 and cover 40 are formed from sheets that are laminated to the underlying layers of the receiver assembly 2 using flat plate module manufacturing techniques and materials. Note from FIG. 4 that layer 38 and cover 40 have central ridges running along the length of receiver assembly 2. These ridge features result from manufacture when layers 38 and 40 are laminated into the assembly using heat and pressure as the layers conform to the underlying features of the substrate contour (if any), the cells 34, and the wiring interconnections 36. Thus, the materials used for layers 38 and 40 desirably are thermoformable when these layers are formed from pre-existing films.

In a particularly preferred embodiment of receiver assembly 2 shown in FIG. 4 laminated using flat plate module manufacturing techniques and ribbon wire interconnections, the substrate 30 includes a contour 31 underlying the ribbon wire interconnections 36 and also is a thermally conductive aluminum plate acting as a structural support and heat spreader. The contour 31 is preferably in the form of a groove with a trapezoidal profile with rounded corners extending along a length of the substrate. This groove profile helps to avoid cell damage during lamination and through thermal cycling. The lower encapsulant/dielectric layer 32 is a biaxially oriented PET layer such as sourced from a MYLAR OL13 or MELINEX 301H film. Melinex 301H offers the best combination of thermal performance and adhesion. However, in order to ensure complete encapsulation at acceptable performance, EVA film, such as that having a thickness of 8 mils (such as that available from STR) also is recommended for the lower encapsulant. The upper encapsulant layer 38 is an EVA (ethylene vinyl acetate) layer. This invention also teaches that to fully encapsulate the diodes, which may be physically bulky, a thick upper layer of EVA, at least 36 mils, is recommended. The cover 40 is sourced from a TEFZEL brand film (modified ethylenetetrafluoroethylene, ETFE) available from DuPont. The cover system of the EVA/TEFZEL films was found to successfully pass 4 lb and 20 lb push tests of UL1703. Cut tests induced no critical damage to the test vehicle resulting in no weakening of the dielectric properties and hence no reduction in safety of the system. The combination of the grooved substrate and the PET/EVA encapsulation and dielectric isolation yielded performance data to indicate that this combination would help produce the required power output and survive environmental stressors without significant degradation. This particularly preferred design is expected to produce adequate power and survive environmental stressors without significant degradation.

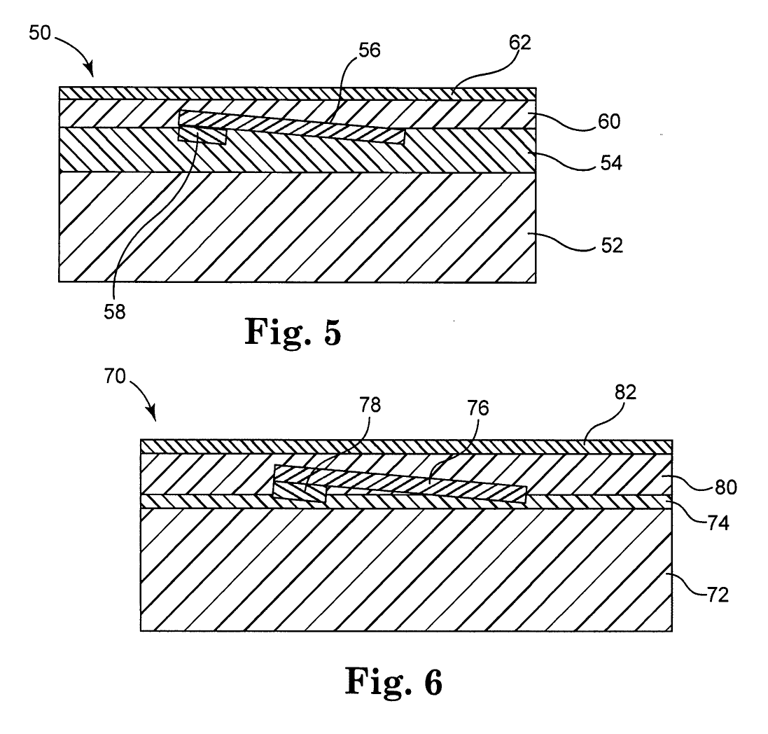

FIGS. 5 through 8 illustrate alternative options for various substrate and lower encapsulant/dielectric layer geometries. FIG. 5 illustrates a cross-sectional end view of an illustrative, laminated receiver assembly 50 using a relatively thick lower dielectric/encapsulant layer 54 and a flat substrate 52. Cells 56 and ribbon wire 58 are encapsulated between upper encapsulant layer 60 and lower encapsulant layer 54. A cover 62 overlies the upper encapsulant layer. An embodiment such as that shown in FIG. 5 may have excellent mechanical, electrical, and environmental properties, but may have reduced thermal performance due to the relatively thicker lower encapsulant layer 54.

FIG. 6 illustrates a cross-sectional end view of another illustrative, laminated receiver assembly 70 using a thin dielectric layer 74 and a flat substrate 72. Cells 76 and wire 78 are encapsulated between upper encapsulant layer 80 and lower encapsulant/dielectric layer 74. A cover 82 overlies the upper encapsulant layer.

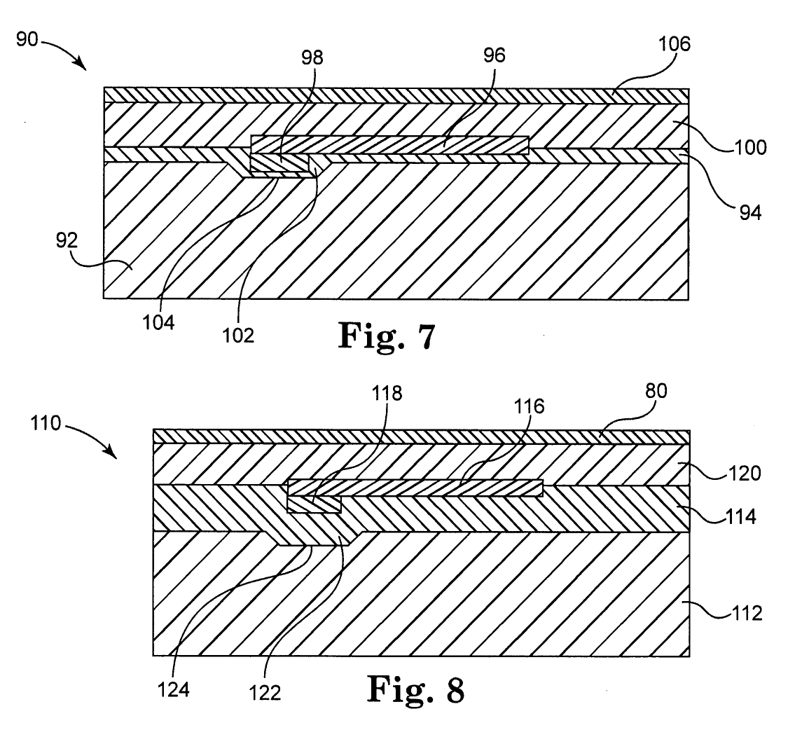

However, as discussed above, as the lower encapsulating layer becomes thinner (e.g., approaching the thickness of the interconnecting ribbon wire), the present invention appreciates that there is an increasing motivation to contour the substrate to the profile of the cell and ribbon wire. This contour strategy helps provide excellent thermal performance of a thin encapsulant layer while providing at least a minimal thickness of encapsulant in order to achieve dielectric standoff. The contour also helps avoid the creation of potentially damaging excessive mechanical stresses during lamination. Thus, FIG. 7 illustrates a cross-sectional end view of an illustrative receiver assembly 90 using a thin dielectric layer 94 and a contoured substrate 92. Cells 96 and ribbon wire 98 are encapsulated between upper encapsulant layer 100 and lower encapsulant layer 94. A portion of the wire 98 fits into the pocket 102 formed by contour 104 in substrate 92. A cover 106 overlies the upper encapsulant layer 100. A contoured substrate will decrease the thermal impedance between substrate and the cell as well as reduce the chance of cell breakage as shown in FIG. 7. This strategy also allows the lower encapsulating layer to be much thinner to increase thermal transfer to the substrate while still electrically insulating the cell wiring from the underlying substrate.

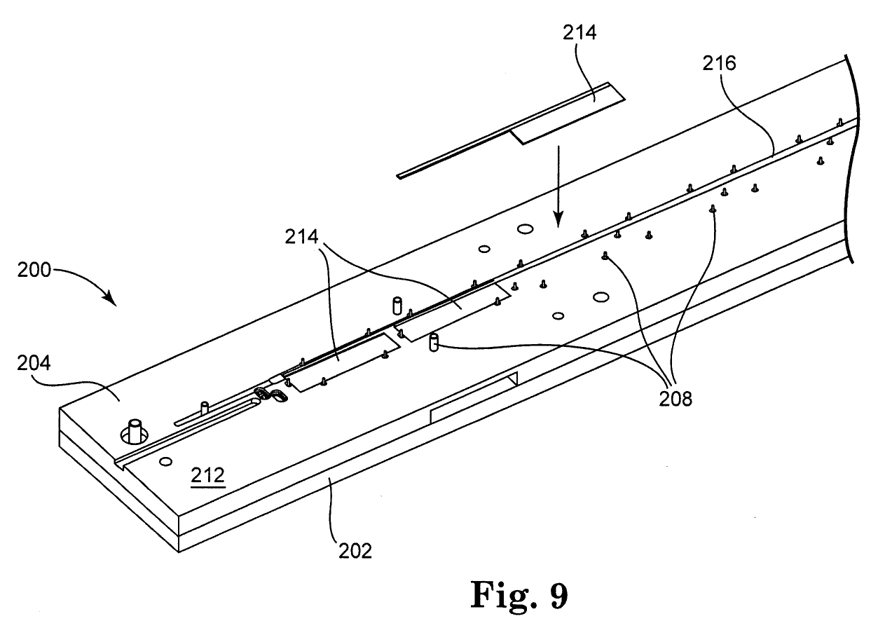

Yet, a contoured substrate would be desirable even when the lower dielectric layer is thicker such that the cells and wire lie above and outside the pocket formed by the contour. For example, FIG. 8 illustrates a cross-sectional end view of another illustrative receiver assembly 110 using a thick dielectric layer 114 and a contoured substrate 112. Cells 116 and wire 118 are encapsulated between upper encapsulant layer 120 and lower dielectric layer 114. Note in this embodiment that portions of the wire 118 that are beneath the cells 116 are above the pocket 122 formed by contour 124 in substrate 112. Comparing this FIG. 8 to FIGS. 5 and 6, the presence of pocket 122 allows the cells 116 and wire 118 to sit more level in the laminated structure. A cover 80 overlies the upper encapsulant layer 120.

The components of receiver assemblies are assembled with a desired degree of precision, particularly so that the wiring is properly positioned with respect to underlying contours in the substrate in those embodiments including a contoured substrate. A fixture was developed to assist with the stringing, lay-up, and lamination of receiver assemblies. The fixture helps to position the cells, wiring, and diodes during stringing, assists with alignment during lay-up, and then maintains alignment during transfer to the laminator and during lamination. The jig uses a large number of retractable alignment pins that assist with tabbing alignment but that can be removed during transfer to the laminator. An overview of the jig and its use is shown in FIGS. 9 through 14.

Referring to FIGS. 9 through 14, the jig 200 includes a pin carrier 202, a base 204, and a clamping board 206. The pin carrier 202 includes a number of upwardly projecting alignment pins 208 that correspond to the positioning of receiver components on the base 204. The base 204 includes corresponding holes 210 so that when the base 204 and pin carrier 202 are assembled, the pins 208 project through the base 204 to help with alignment. The base 204 includes recesses to further assist with the positioning of elements in the jig 200.

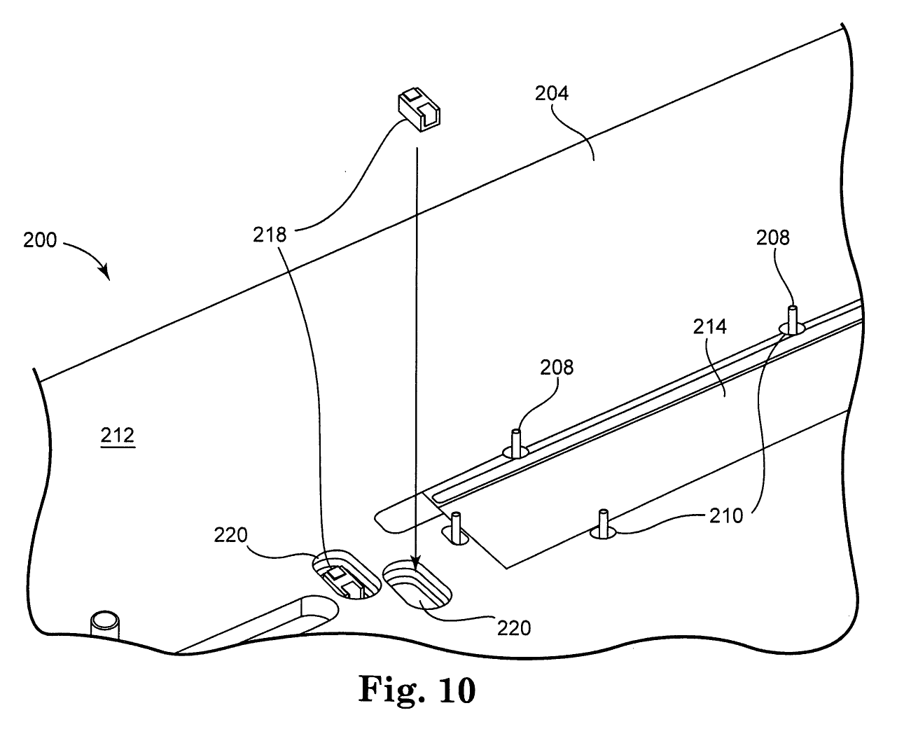

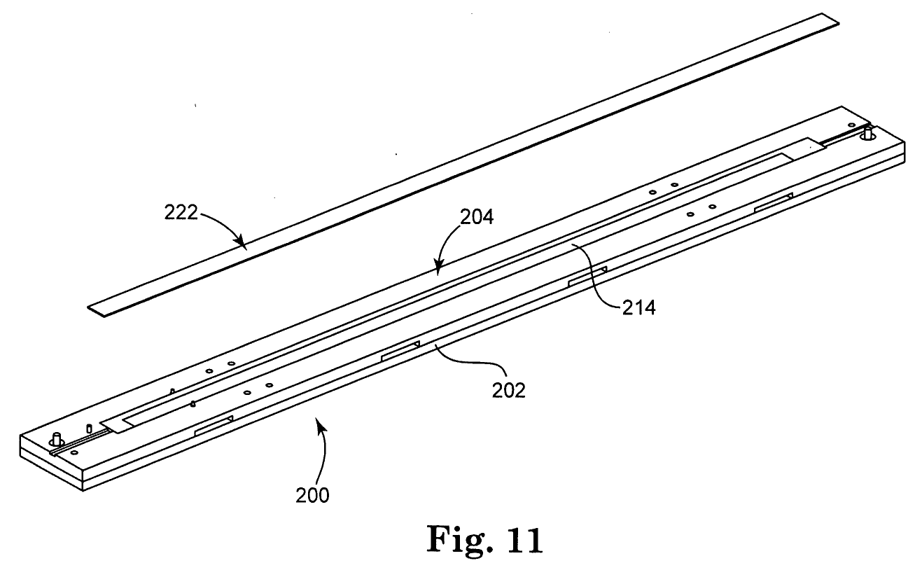

In FIGS. 9 through 10, the features shown are designed to allow the relevant portions of the receiver assembly 2 to be assembled “upside down”, with the substrate (incorporated into a pre-assembly 222) being on top as seen in these Figures. As shown in FIG. 9, the base 204 and pin carrier 202 are initially assembled so that the pins 208 project upward through the base 204. In this orientation, the current “top” face 212 of the jig 200 is oriented toward what will be the cover side of the resultant receiver assembly. Tabbed cells 214 are positioned on the jig 200. The pins 208 and a groove 216 help with this positioning. Next, as shown in FIG. 10, diodes 218 are placed into position using recesses 220 in base 204 to assist with positioning. A lower encapsulant/dielectric layer has been pre-laminated to a substrate and then, as shown in FIGS. 10 and 11, this pre-assembly 222 is placed over the tabbed cells 214 and diodes 218, using the pins 208 to assist with alignment, with the pre-laminated side of the pre-assembly 222 bearing a dielectric layer facing the base 204.

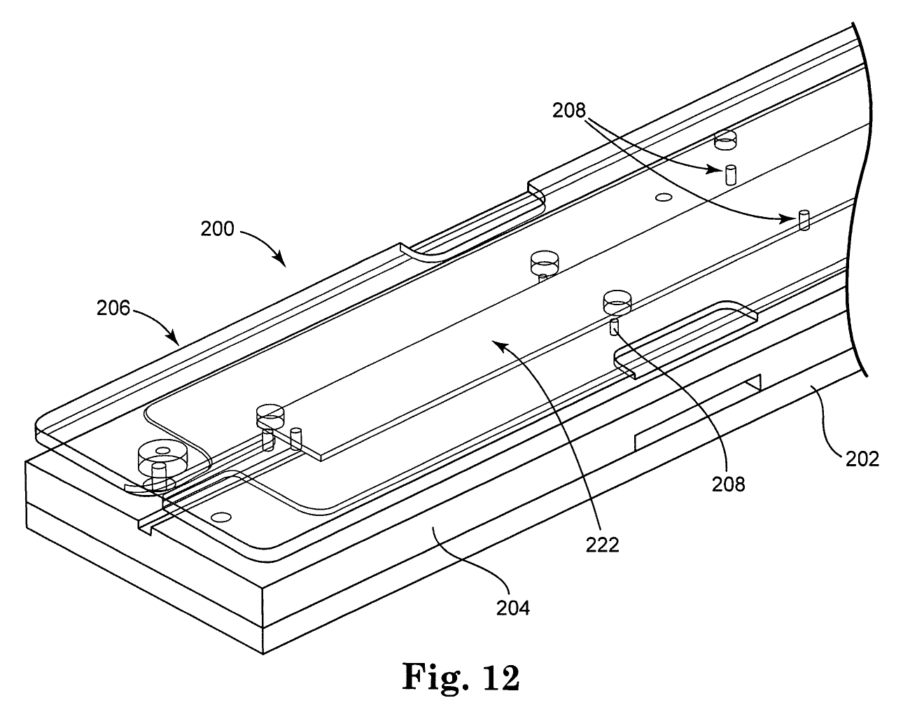

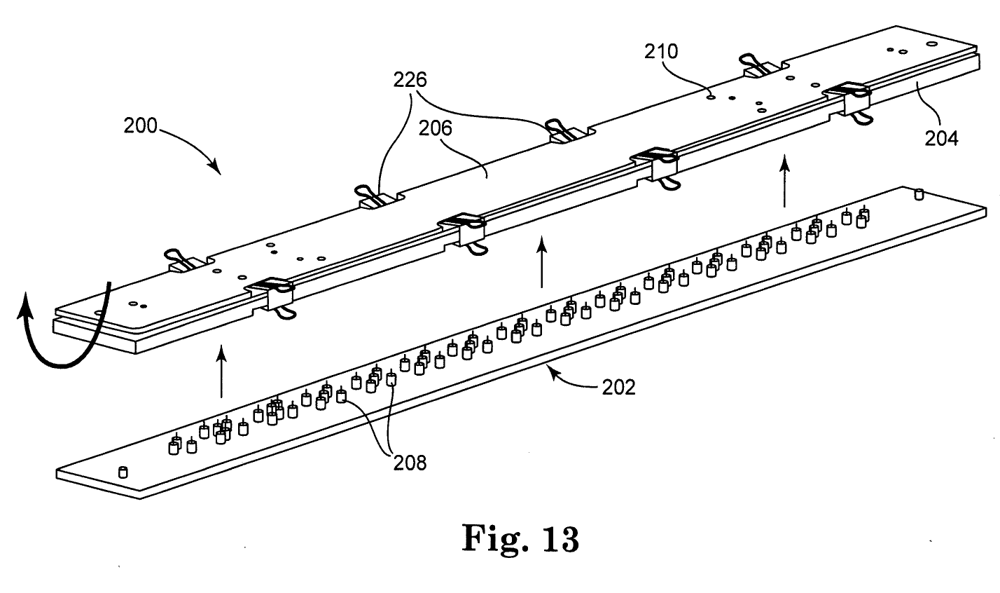

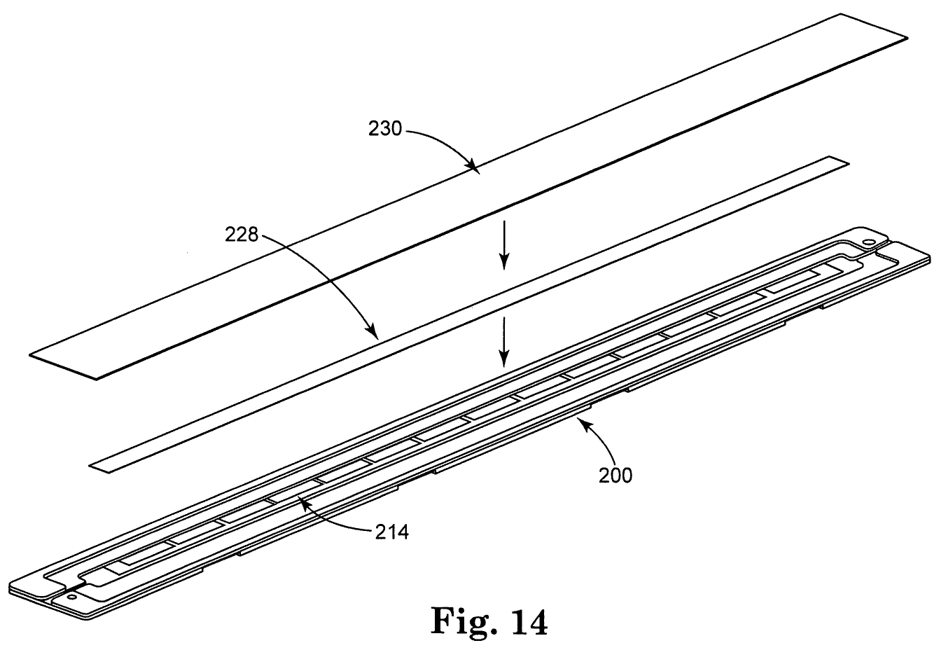

FIGS. 12 and 13 show how a clamping board 206 is then secured to the base 204 using clamps 226 or other suitable securement to hold all the components in the lay-up positions. As shown in FIG. 13, the pin carrier 202 can be slowly removed and the assembled base 204 and clamping board 206 can be flipped over. As shown in FIG. 14, sheets 228 and 230 corresponding to the top encapsulant layer and the cover, respectively, can then be laid into position. Recess features on the face of the jig 200 assist with positioning of sheets 228 and 230. Lamination can now be carried out with the components held in the jig.

The approach shown in FIGS. 9 through 14 involves direct lamination of diodes into a receiver assembly. However, this approach can cause wrinkles to develop in an ETFE cover sheet. Another issue is that the diodes might not become fully encapsulated. A number of strategies can be used to address these lamination issues concerning diodes. First, the diode profile can be smoothed prior to lamination by adding an adhesive fillet or cap to pre-encapsulate the diode. Second, a small hole can be cut in the ETFE cover layer through which the diode would protrude, relieving the stress in the ETFE and minimizing the area that had to be filled by EVA encapsulant. Third, a hole can be cut in the aluminum substrate, and the diode can be soldered in place so that the diode protrudes into this hole. Fourth, more or thicker layers of EVA can be added directly over the diode, or over the entire receiver. Adjusting the lamination parameters, such as by reducing the lamination pressure from 14.7 psi to 11.8 psi further assisted this method.

All of the solutions described above were evaluated and address the issue to some degree. The results are summarized in the following table. The preferred technique involves increasing the total thickness of the EVA above the diode. In the near term, this was accomplished by using 2 layers of 18 mil EVA. For future builds, it makes sense to move to a single layer, currently commercially available in thicknesses up to 40 mils for example.

Voids

| Technique | Frequency | Size | Wrinkles |
|---|---|---|---|
| Baseline: 18 mil | Always | Large | Significant |
| EVA, high pressure | | | |
| Fillet Encapsulation | None | n/a | Moderate |
| Full Encapsulation | None | n/a | Significant |
| (Cap) | | | |
| ETFE hole | Few | Small | Moderate |
| Hole in Substrate | None | n/a | None |
| 18 mil EVA, lower | Usually | Medium | Moderate |
| pressure | | | |
| 36 mil EVA, lower | Rarely | very small | Very Slight |
| pressure | | | |
| 54 mil EVA, lower | None | n/a | None |
| pressure | | | |
| 72 mil EVA, lower | None | n/a | None |
| pressure | | | |

Ribbon shifting is another lamination issue that may occur. During lamination, in the transition between EVA melting and cross-linking, the flowing of the EVA can cause parts of the laminate to shift slightly. This phenomenon is normally tolerable in standard flat plate modules. However, the issue of ribbon shifting is exacerbated in the current receiver design for a few reasons. First, the receiver is less tolerant to positional shifts, because the unsupported lengths of ribbon are fairly long. Also, the spacing between the ribbon and other electrically live parts is very tight, nominally only 1 mm. Second, the driving forces for ribbon shifting are higher. On one hand, the ribbons are fairly close to the edge of the module so that the EVA will tend to flow outward. On the other hand, the contour of the vacuum bladder as it bends around the substrate will tend to push the ribbons inward. Additionally, the thickness of the lower encapsulant layer, which may be EVA in representative embodiments, is thinner than in traditional solar panels. To make the thinner EVA sheet that is desirably used in the present invention, the material undergoes more forming operations and this will tend to cause it to shrink more than thicker EVA. This will tend to pull the ribbons inward.

Given the above factors, it is not clear which direction the ribbon will shift during lamination, as there are unquantified forces in multiple directions. The initial laminations of the full-length receivers indicate that ribbon shifting tends to inward slightly, on the order of 0.75 mm.

A number of experiments were performed to assess the magnitude of ribbon shifting effects to devise ways to control the ribbon position. These strategies include
1) adding spacer bars of different thickness on the side of the substrate to change the direction of pressure from the lamination membrane (more details on this are below),
2) putting thin EVA only under the cells, not under the ribbons, and 3) taping the ribbons down to the substrate or EVA

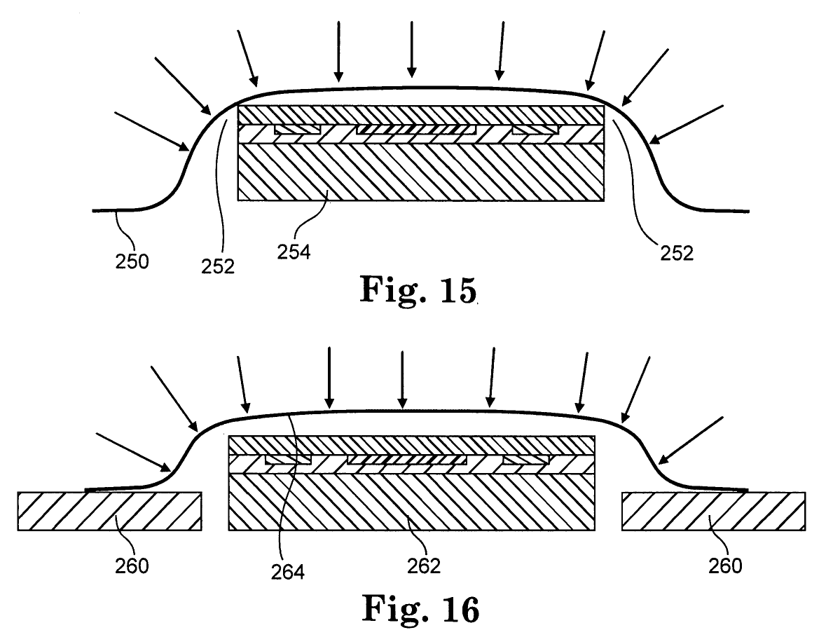

It was observed that one of the more sensitive parameters that could be adjusted is the profile of the vacuum bladder near the edge. The conceptual model of how this works is illustrated in FIG. 15. As bladder 250 curves around the edges 252 of the receiver assembly 254, the normal force of the bladder 250 will either tend to push material inward (if the bladder applies pressure in a concave shape) or outward (if the bladder applies pressure in a convex shape). One easy way to control this is to add spacers of different thickness proximal to the edges 252 of the receiver 254, as is commonly done in the display industry.

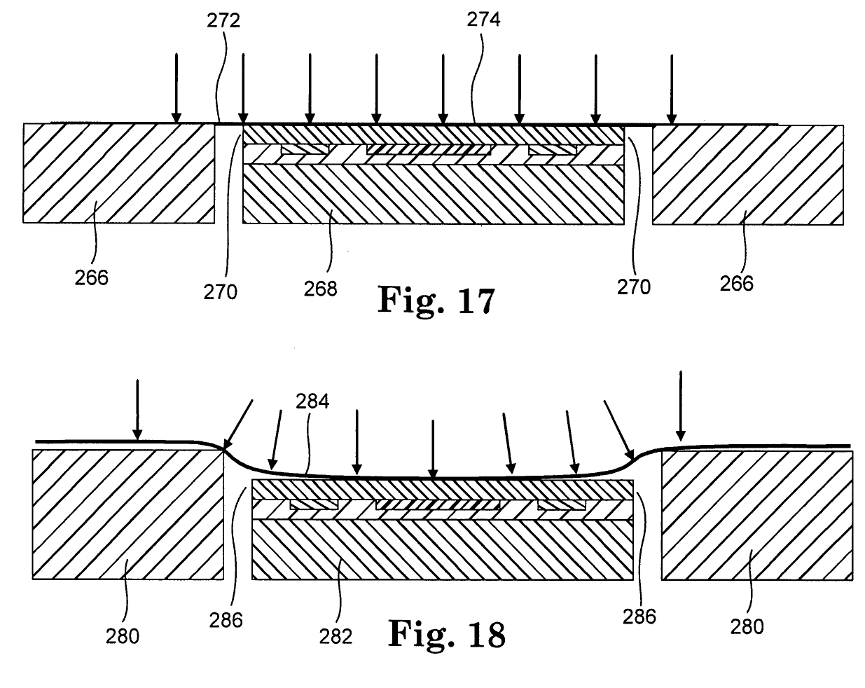

Spacer strategies are shown in FIGS. 16 through 18. In FIG. 16, spacers 260 are used that are shorter in height than the receiver assembly 262. The resulting bladder force imparted by bladder 264 has less inward force at the edges compared to the bladder forces shown in FIG. 15. In FIG. 17, spacers 266 are the same height as receiver assembly 268. There is no net inward or outward bladder force at the edges 270 imparted by bladder 272. The bladder force acts normal to the top face 274 of the receiver 268. In FIG. 18, the spacers 280 are taller than the receiver assembly 282. The resulting bladder force resulting from bladder 284 has a net outward force near the receiver edges 286.

To evaluate bladder force as a function of spacer thickness, six experiments were conducted. They are summarized in the following table. The batch-to-batch variation is difficult to estimate due to the small number of samples tested.

| | | | | | Estimated shift |
|---|---|---|---|---|---|
| Experiment | Spacer | Tape | Lower EVA | Result | (+ is outward) |
| 0 | None | None | Full width | Ribbon shifting | −0.75 mm |
| | | | | inward | |
| 1 (side one) | Thick 0.125″ | None | Full width | Very large | 6 mm |
| | | | | outward shift | |
| 1 (side two) | Thin 0.063″ | None | Full width | slight inward shift | −0.25 to −.5 mm |
| 2 | Thick 0.125″ | Yes | Full width | Very large | 6 mm |
| | | | | outward shift | |
| 3 | Equal 0.100″ | None | Full width | Outward shift | 2-4 mm |
| 4 | Equal 0.100″ | Yes | Partial Width | No significant | None |
| | | | | shift | |
| 5 | Equal 0.100″ | None | Partial Width | No significant | None |
| | | | | shift | |
| 6 (repeat of exp. | Equal 0.100″ | None | Partial Width | No significant | None |
| 5 but with | | | | shift | |
| diodes) | | | | | |

The results of these experiments indicate that ribbon shifting shows a very strong dependence on bladder shape (influenced by the height of spacers, if any, relative to the height of the receiver assembly). A convex bladder shape is universally bad. This data shows that for the particular receiver assembly tested, there may be an ideal spacer thickness between 0.063 inches (1.6 mm) and 0.100 inches (2.54 mm) that shows net zero ribbon shifting. It appears there is some natural tendency for the ribbons to drift towards the edges of the module as the EVA flows outward. However, the effect of the bladder shape is much stronger. Taping the ribbon to the cells or substrate did not have a significant effect. Removing the EVA below the ribbons was beneficial. This removal did not lead to the formation of voids but did significantly reduce the drifting of the ribbons. In conclusion, to maintain the position of the ribbon relative to the cells, spacers to control the bladder profile, and partial width lower encapsulant, are recommended.

The interconnects of the test vehicles were not encapsulated for convenience. For the test units, it was decided that the most expedient solution would be to directly pot the solder connection. Otherwise, a junction box is preferred. A difficulty with potting with or without a junction box is adhering reliably to the ETFE cover sheet in those embodiments in which the cover is made from this material. The additional difficulty when potting the wire without a junction box is that the pottant viscosity must be very high to fully encapsulate the wire. Samples were ordered of a number of adhesives and potting compounds and trials were run to evaluate adhesion. Based on the trial runs, a cyanoacrylate-based adhesive is the best candidate for adhering to the ETFE in those embodiments including ETFE material. In fact, of the adhesives tested, cyanoacrylate-based adhesive was the only adhesive that adhered at all to ETFE. In addition, there are formulations available with the appropriate viscosity for direct potting. The preferred cyanoacrylate-based adhesive for this application is the HP1000 adhesive applied with the Polyprep pretreatment and using the activator to instantly cure during application. The HP10000 is black so it will resist discoloration from UV light. Using this adhesive, the potted wire passed a 2200V HiPot test.

| | | | Primer | Adhesion | Viscosity | |
|---|---|---|---|---|---|---|
| Manufacturer | Product | Base | Used | results | Results | Other Notes |
| 3M | DP 125 | Epoxy | None | Fail | Fail | |
| Adhesive | MP54125 | Epoxy | None | Fail | Fail | |
| Systems | | | | | | |
| Dow Corning | Sylgard 170 | Silicone | None | N/A - not | Fail | Did not run |
| | | | | likely to | | potting test - |
| | | | | work | | material was the |
| | | | | | | not nearly |
| | | | | | | viscous enough |
| Resinlab | AR4315 | Methacrylate | loctite 770 | Fail | Pass | |
| Adhesive | SI Gel | Cyano- | Poly-prep | Pass | Pass | Does not look |
| Systems | | acrylate | | | | very good |
| | | | | | | visually after |
| | | | | | | cure since it is |
| | | | | | | clear in color. |
| | | | | | | Using Activator |
| | | | | | | speeds up the |
| | | | | | | cure and creates |
| | | | | | | a nicer surface. |
| Adhesive | HP10000 | Cyano- | Poly-prep | Pass | Pass - | Activator |
| Systems | | acrylate | | | when using | causes adhesive |
| | | | | | activator | to instantly |
| | | | | | | cure. When |
| | | | | | | sprayed onto |
| | | | | | | adhesive the |
| | | | | | | outer layer |
| | | | | | | cures and forms |
| | | | | | | a shell that |
| | | | | | | holds its shape. |

During vacuum lamination, a number of additional factors governing the selection of preferred design aspects of the lamination of receiver assemblies were discovered. These were related to the 1) required temperatures and pressures, 2) substrate pretreatment, and 3) material off-gassing. The laminator that was used for the prototyping (P Energy 150A) has the capability to heat to a temperature of 180° F. and apply 14.7 psi pressure. This proved to be insufficient to activate the thermal adhesive of the PET material and was also insufficient to cause the silicone material to properly flow and function as an encapsulant. The silicone material was tested using the marginal lamination parameters, and the PET was laminated in a separate step using a flat platen press.

Significant difficulties were encountered when scaling the PET lamination process from small, 13-inch samples to the full-sized 39-inch receivers. The initial samples were tried on a small flat platen heat press. When scaling up, a roller type laminator was used to accommodate the long length. However, it proved exceedingly difficult to implement this in practice consistently along the length of the receiver assembly. The difficulties were attributed to the substrate acting as a large heat sink and pulling heat away from the area where the pressure was applied. Based on these initial setbacks, the use of large flat platen presses is proposed.

The sheet materials (such as the Tedlar and EPE sheet materials) without an integral adhesive layer require pretreatment of the aluminum. A suitable pre-treatment involves treatment with a chromate conversion and solvent-based adhesive to promote adhesion. The epoxy coating (Castall 343 A/B) exhibited problems with off-gassing during vacuum lamination, leading to large areas of trapped gasses. Due to these problems, this material was not explored further.

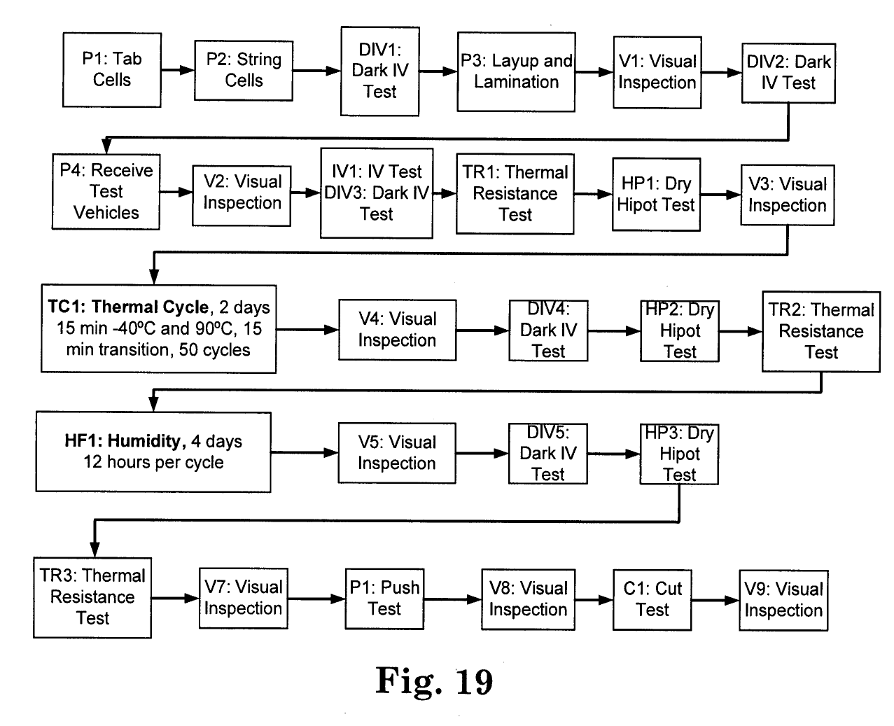

Receiver assemblies having 4 cells were tested using the testing sequence shown in FIG. 19. This testing sequence is based on a simplified version of the test sequence specified in UL1703 for flat plate modules. Notably, the thermal cycling and humidity freeze steps are modified to dramatically shorten the total test cycle time.

All IV (current-vs.-voltage) curves were taken using a Keithley 2420 SourceMeter (bipolar power supply), four-point measurement, and IV test software of GreenMountain Engineering, LLC, San Francisco, Calif. Dark IV curves were taken to 3A forward bias. One-sun and concentrated-sunlight IV curves were taken at the rooftop testing facility of GreenMountain Engineering.

Insolation measurements were taken using an Apogee PYR-S pyranometer, and ambient temperature measurements were recorded using type K surface mount thermocouples. IV data was processed and parameters extracted using ECN's IVFIT using orthonormal regression curve fit software. IV data was normalized for insolation, but not for temperature. Temperature was controlled during a single test sequence using a water cooled thermal chuck.

For the Hi Potential test, the prototype receivers were tested according to UL1703 using a QuadTech Sentry 30 HiPot tester. The voltage was ramped from 0-2200V over 5 seconds and then held at 2200V for 60 seconds. The threshold leakage current for a failure was set to 10 μA.

The thermal cycle and humidity/freezing environmental tests were conducted at Quanta Labs in Santa Clara, Calif. The profiles used were modified and abbreviated versions of those used in UL1703. The ramps and soak times were shortened and total number of cycles was reduced in an effort to expedite development time (from 2 months to 1 week). Table 5 shows a comparison of the cycles used herein with those recommended in UL1703. It was thought that the cycle times could be reduced due to the much reduced thermal mass and path length for moisture absorption. However, it is freely acknowledged that these cycles will be less severe than those expected in UL testing. The purpose of this shortened testing was to 1) select between competing designs, and 2) get an idea of the types of issues that might arise during UL testing, but not to fully pre-qualify the design for UL testing.

| | Thermal Cycle | | | | Humidity Freeze | | | |
|---|---|---|---|---|---|---|---|---|
| | UL1703 | | Accelerated | | UL1703 | | Accelerated | |
| Number of Cycles | 200 | | 50 | | 10 | | 10 | |
| Cycle time | 3-6 | hours | 1 | hour | 24 | hours | 12 | hours |
| Total time | 25-50 | days | 2 | days | 10 | days | 5 | days |
| Ramp up time | 1 | hr | 15 | min | ~1 | hr | 1 | hr |
| High temp Soak | ~1 | hr | 15 | min | 20 | hr | 9 | hr |
| Ramp down time | 1 | hr | 15 | min | ~1 | hr | 1 | hr |
| Low temp soak | ~1 | hr | 15 | min | ~1 | hr | 1 | hr |
| time | | | | | | | | |

| | | | | |
|---|---|---|---|---|
| Humidity | n/a | n/a | 85% | 85% |

Thermal resistance was estimated by the following process. First, V_{OC} and I_{SC} are measured in thermal equilibrium under 1 sun. The cells are coupled to a water cooled heat exchanger using a 1 mil double-sided Kapton tape. Then, V_{OC} and I_{SC} are measured in thermal equilibrium under concentrated light. The measured value of concentrated I_{SC} is compared to the 1 sun I_{SC} and is used to determine the optical concentration factor. The expected V_{OC} in thermal equilibrium is calculated using the formula

V_{OC}_{_{—}}_{Cx}=V_{OC}_{_{—}}₁ₓ+0.025N_{J} ln (C)

where C is the concentration factor and N_{J} is the number of junctions. The thermal resistance is calculated from the difference in measured and expected Voc under concentration using the temperature coefficient for V_{OC} for the cells (2.225 mV/C), as provided by NaREC, the manufacturer of the cells used in these tests. However, the data generated using this procedure was too noisy to allow statistically significant comparisons. It would be more desirable, therefore, that thermal resistance measurement be conducted based on time vs. V_{OC} measurements.

Push and cut tests were performed using equipment to approximate the test setups described in UL1703. Push test 1 was performed by using a push-pull meter (10 lb dial) applying 4 lbs of force on a 1/16 inch diameter ball for 1 minute. Push test 2 was performed by using a block to put 20 lbs of force on a ½ inch diameter ball for 1 minute. On push test 2, force was measured using a digital scale. For both tests, the force was applied on the top surface of the receiver in two places: in the middle of the cell and on a junction between cells.

The cut test was performed using a broken hacksaw blade, pushed onto the cell with 2 lb of force and with a 10 lb push pull scale. The blade was held in place for 1 minute and then the test vehicle was dragged under the blade at a rate of around 6 in/s.

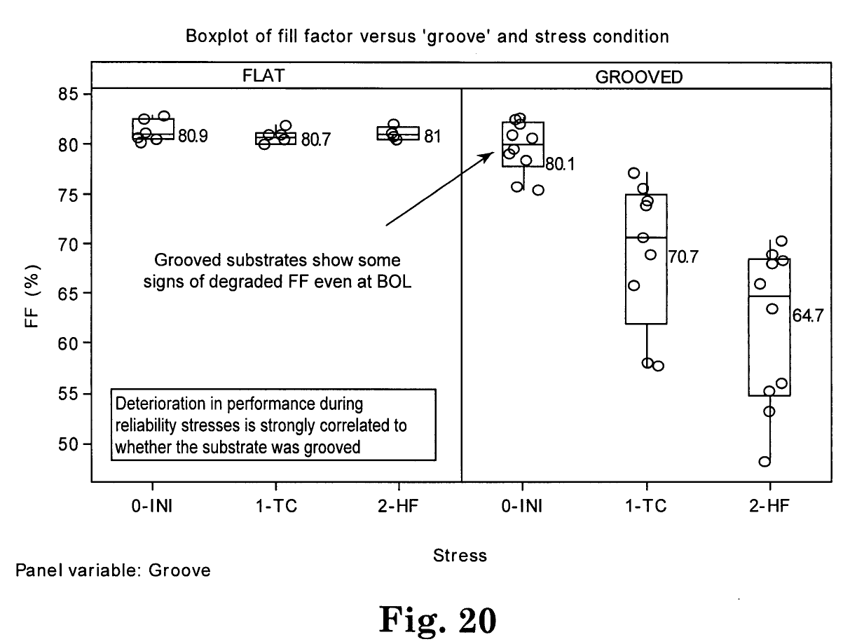

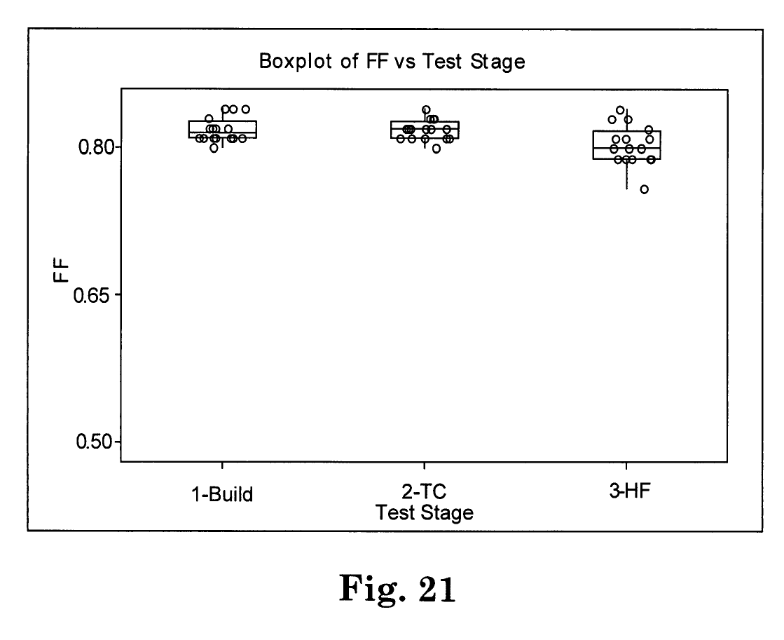

The environmental test results overwhelming indicate that using a substrate with a trapezoidal groove with rounded corners is an improvement over using a substrate incorporating a simple square groove. This is shown in FIGS. 20 and 21. In FIG. 20, a boxplot of the fill factor (a measure of solar cell performance) as a function of stress substrate geometry is shown. In FIG. 20, the fill factor at beginning of life, after thermal cycling, and after humidity freeze for samples having substrates with a simple square groove are shown compared to the results for samples having a flat substrate. The samples with square groove substrates show substantial performance degradation after thermal cycling (TC) and humidity freeze (HF). Looking at the degree of degradation observed using the square profile, it is clear that many of the cells were broken during lamination, most likely due to sharp corners and depth of the simple groove.

In contrast, FIG. 21 shows a similar boxplot of fill factors for test assemblies including a substrate having a trapezoidal groove with rounded corners. These test samples showed vastly superior environmental stability as compared to the substrate with the square groove. The fill factor remained very stable after thermal cycling and humidity/freezing exposure. In trying to differentiate between the samples with the trapezoidal groove and those with a flat substrate (no groove), no conclusions can be drawn with confidence, for a few reasons. First, there were only two flat samples tested, whereas eight substrates with trapezoidal grooves were tested. Second, the flat substrates were constructed using the silicone encapsulant listed above, causing both of the substrates to fail at some point in the test sequence, further reducing the sample size. Third, no flat substrates in this test were constructed with a known good encapsulation and dielectric system.

Despite these caveats, the IV performance degradation observed in the flat substrates was minimal. This data, in addition to engineering judgment and experience with other modules, suggests that flat substrates constructed with 8 mil EVA and a proven dielectric should show environmental performance comparable to the samples that include a trapezoidally grooved substrate. However, the grooved samples are believed to have improved thermal coupling.

The dielectric material selection is influenced by a number of factors. Most paramount is an ability to maintain dielectric standoff reliably through thermal cycling. In addition, the material should be manufacturable, meaning that it readily adheres to the aluminum substrate in those embodiments including an aluminum substrate and reliably encapsulates the cells. Further, as environmental stressors are applied, its adhesion and encapsulation properties should not degrade below allowable levels. Finally, it should not contribute to IV performance degradation of the cells through environmental testing. The following table compares representative dielectric and encapsulation systems discussed against these factors.

| | | | Adhesion after | |
|---|---|---|---|---|
| | | Dielectric | Environmental | |
| Dielectric/Encapsulant | Manufacturing | Performance | Testing | IV Performance |
| Bergquist Bond Ply LMS | Insufficient Pressure, | Immediate FAIL | Good adhesion, voids | Poor (significant |
| | Encapsulation | | became larger | degradation) |
| | Problems | | | |
| STR EVA with Scrim | Good lamination | Immediate FAIL | Not tested | Not tested |
| Tiger Drylac Series 49 | Good lamination | FAIL after | Good | Poor with Silicone |
| | | humidity | | encapsulant |
| Tiger Drylac Series 49 | Good lamination | PASS | Good | Good, with 8 mil |
| with anodized layer | | | | EVA |
| Polane-S Polyurethane | Good lamination | FAIL after | Good | Fair, with 8 mil EVA |
| with anodized layer | | humidity (50%) | | |
| Castall 343 A-B | Offgassing issues | Not tested | Not tested | Not tested |
| Mylar OL13 | Good lamination on | PASS | Fair to Poor | Good |
| | flat press, many | | | |
| | difficulties with nip | | | |
| | rollers | | | |
| Melinex 301H | Good lamination on | PASS | Good to Fair | Good |
| | flat press, many | | | |
| | difficulties with nip | | | |
| | rollers | | | |
| Madico EPE | substrate must be | Not tested, | Not tested | Not tested |
| | primed with | assumed PASS | | |
| | conversion coating | | | |
| | and solvent based | | | |
| | adhesive, not tested | | | |
| Tedlar | Substrate must be | Not tested, | Not tested | Not tested |
| | primed with | assumed PASS | | |
| | conversion coating | | | |
| | and solvent based | | | |
| | adhesive, good | | | |
| | lamination | | | |
| | performance at JMP | | | |

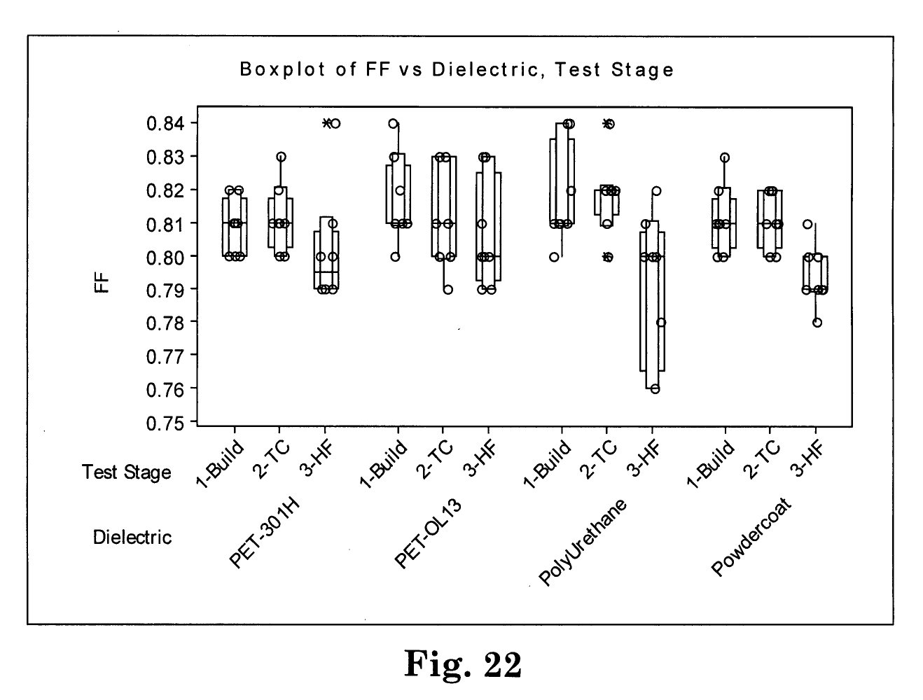

The relative IV performance for a selected group is shown in FIG. 22. There, fill factor performance versus environmental stressor is shown for selected dielectric layers, including the 301H polyester, the OL13 polyester, the polyurethane, and the powdercoat. Fill factor is shown for each of these at the initial (build) condition, after thermal cycling (TC), and after the humidity/freezing cycle (HF).

From the results shown in the dielectric table and in FIG. 22, a few general conclusions can be reached. First, non-continuous dielectric layers such as glass fiber or glass beads provide less reliable dielectric standoff. Second, electrically insulating coatings, including surface finishes, powder based finishes, and liquid coatings provide marginal dielectric protection at best, at least at thicknesses that provide reasonable thermal performance. Third, solid film dielectrics are reliable dielectrics. However, there can be significant process difficulties when reliably bonding these directly to aluminum. Further, given the two encapsulating materials considered in these tests, EVA and silicone sheet, the EVA more reliably encapsulates at conventional lamination pressures and temperatures. It is likely that if pressures or temperatures were significantly raised, cell damage would start to occur. TEDLAR sheet on aluminum using the DuPont adhesives appears to be a promising dielectric solution also. Based on the results described above, the MELINEX 301H PET material was identified as a preferred option for the lower encapsulant/dielectric layer.

Push and cut test results for samples including a TEDLAR cover and EVA upper encapsulant layer indicated that the push and cut test would not be a major concern for any of the current designs. Comments on the push test results are shown in the following table.

| Where on | | |
|---|---|---|
| Vehicle | 4 lb Push Test | 20 lb Push Test |
| On Cell | Slight cracking was heard during the | Slight cracking at start, |
| | test, there could have been some cell | then no sound. There |
| | damage. There was a divot in the | was a large divot in |
| | receiver, but it did not seem to go all | the encapsulant, but it |
| | the way to the cell. | did not go through to |
| | | the cell. |
| On | A slight divot was made, but it did | A slight divot was |
| Junction | not open to the tabbing. | made, but it did not |
| | | open to the tabbing. |

For the cut tests, a scratch was visible after the test, but it was not clear visually if this went through to the cell. The cut did not seem to go through to the cell based on physical examination by running a multimeter probe through the cut.

After push and cut testing, a multimeter was used to check continuity between the busbars and the points that were affected by the push and cut tests. One probe was pushed through the EVA to make contact with the busbar. The other probe was lightly pressed onto the portions of the receiver affected by the test above a gridline or busbar. For the cut test, the probe was run through the cut groove. For all points, no continuity was read leading us to believe that there was no major breakthrough to the cell or junctions during the push and cut tests. This was a simplified test and does not assure there was no dielectric breakdown.

A version of the leakage current test was performed with a HiPot tester set to 600V. Leakage current was measured as 2 μA which is less than the 10 μA maximum stated by the UL specification. However, this was not a true leakage current test, for which we would need a different machine that includes an inductive circuit that simulates the leaked current flowing through a person. For this reason, the HiPot result cannot be directly compared to the UL spec.

Regardless, no critical damage was sustained by the test vehicle and the push and cut tests did not result in a weakening of the dielectric properties, and hence the safety, of the system. For this reason, we see no reason to suspect that the modules will not pass the push and cut tests during UL approval. A true HiPot test was not possible since the test vehicle in question did not pass the HiPot before the push and cut tests, so there is no quantitative confirmation of this conclusion.

For a more thorough testing push and cut test, a leakage current test device would be needed to test the leakage current before and after the tests. Alternatively, if the initial receivers pass the HiPot test, the HiPot test could be used to qualify the receivers after push and cut testing.

The complete disclosures of the patents, patent documents, and publications cited herein are incorporated by reference in their entirety as if each were individually incorporated. Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

What is claimed is:

1. A photovoltaic concentrator module, comprising:
a photovoltaic receiver assembly; and
an optic that concentrates incident light onto the receiver assembly; and
wherein the photovoltaic receiver assembly comprises at least one wired photovoltaic cell supported upon and thermally coupled to a thermally conductive substrate, said wired photovoltaic cell comprising a wiring interconnection electrically coupled to the cell, and
wherein the receiver assembly comprises a dielectric layer interposed between the at least one wired photovoltaic cell and the substrate to help electrically isolate the wired photovoltaic cell from the substrate; and
wherein the substrate comprises a contour underlying the wiring interconnection.

2. The photovoltaic concentrator module of claim 1, wherein the contour comprises an arcuate portion optionally including a changing radius of curvature.

3. The photovoltaic concentrator module of claim 1, wherein the contour comprises first and second planes and a transition interconnecting at least portions of the first and second planes, wherein the transition is rounded at least minimally so as to avoid a line of intersection between at least said portions.

4. The photovoltaic concentrator module of claim 1, wherein the contour comprises a rectangular profile.

5. The photovoltaic concentrator module of claim 1, wherein the contour comprises a generally trapezoidal profile with one or more corners of the profile being generally rounded.

6. The photovoltaic concentrator module of claim 1, wherein at least a portion of the contour comprises a continuous or piece-wise continuous profile of any function.

7. The photovoltaic concentrator module of claim 1, wherein the optic comprises a refractive optical element.

8. The photovoltaic concentrator module of claim 7, wherein the optic further comprises a reflective optical element.

9. The photovoltaic concentrator module of claim 8, wherein the reflective and refractive optical elements serve different portions of the primary aperture of the module.

10. The photovoltaic concentrator module of claim 1, wherein the dielectric layer comprises a polyester film laminated to the substrate.

11. The photovoltaic concentrator module of claim 10, wherein the polyester is biaxially oriented.

12. The photovoltaic concentrator module of claim 1, wherein the dielectric layer is derived from a film having a thickness of less than about 1 mm.

13. The photovoltaic concentrator module of claim 1, wherein the dielectric layer is derived from a film having a thickness of less than about 0.03 mm.

14. The photovoltaic concentrator module of claim 1, wherein the dielectric layer comprises ethylene vinyl acetate.

15. The photovoltaic concentrator module of claim 1 further comprising an upper encapsulating layer overlying the cell in a manner to help encapsulate the at least one wired photovoltaic cell.

16. The photovoltaic concentrator module of claim 15, wherein the upper encapsulating layer comprises ethylene vinyl acetate.

17. The photovoltaic concentrator module of claim 15, wherein the upper encapsulating layer is thicker than the dielectric layer.

18. The photovoltaic receiver of claim 17, further comprising a diode underlying the upper encapsulating layer.

19. The photovoltaic concentrator module of claim 15 further comprising a cover overlying the upper encapsulant layer.

20. The photovoltaic concentrator module of claim 19, wherein the cover comprises ethylenetetrafluoroethylene.

21. The photovoltaic concentrator module of claim 1, wherein the wire interconnection is positioned over and outside the contour.

22. The photovoltaic concentrator module of claim 21, wherein the wired interconnection fits within the contour.

23. The photovoltaic receiver of claim 19, wherein a diode underlies the cover, and the cover includes a hole through which the diode protrudes.

24. The photovoltaic receiver of claim 19, wherein a diode underlies the cover and protrudes into a hole in the substrate.

25. The photovoltaic receiver of claim 19, wherein a filleted diode underlies the cover.

26. The photovoltaic concentrator module of claim 19, wherein each of the upper encapsulant layer and the cover are derived from respective thermoformable films.

27. A photovoltaic receiver, comprising
at least one wired photovoltaic cell supported upon and thermally coupled to a thermally conductive substrate, said wired photovoltaic cell comprising a photovoltaic cell and a wire interconnection electrically coupled to the cell, and
wherein the receiver comprises a dielectric layer interposed between the at least one wired photovoltaic cell and the substrate to help electrically isolate the wired photovoltaic cell from the substrate; and
wherein the substrate comprises a contour underlying the wired interconnection.

28. The photovoltaic receiver of claim 27, wherein the contour comprises an arcuate portion optionally including a changing radius of curvature.

29. The photovoltaic receiver of claim 27, wherein the contour comprises first and second planes and a transition interconnecting at least portions of the first and second planes, wherein the transition is rounded at least minimally so as to avoid a line of intersection between at least said portions.

30. The photovoltaic receiver of claim 27, wherein the contour comprises a rectangular profile.

31. The photovoltaic receiver of claim 27, wherein the contour comprises a generally trapezoidal profile with one or more corners of the profile being generally rounded.

32. The photovoltaic receiver of claim 27, wherein at least a portion of the contour comprises a continuous or piece-wise continuous profile of any function.

33. The photovoltaic receiver of claim 27, wherein the dielectric layer comprises a polyester film laminated to the substrate.

34. The photovoltaic receiver of claim 33, wherein the polyester is biaxially oriented.

35. The photovoltaic receiver of claim 27, wherein the dielectric layer is derived from a film having a thickness of less than about 1 mm.

36. The photovoltaic receiver of claim 27, wherein the dielectric layer is derived from a film having a thickness of less than about 0.03 mm.

37. The photovoltaic receiver of claim 27, wherein the dielectric layer comprises ethylene vinyl acetate.

38. The photovoltaic receiver of claim 27, further comprising an upper encapsulating layer overlying the cell in a manner to help encapsulate the at least one wired photovoltaic cell.

39. The photovoltaic receiver of claim 38, wherein the upper encapsulating layer comprises ethylene vinyl acetate.

40. The photovoltaic receiver of claim 38 wherein the upper encapsulating layer is thicker than the dielectric layer.

41. The photovoltaic receiver of claim 40, wherein a diode underlies the upper encapsulating layer.

42. The photovoltaic receiver of claim 38 further comprising a cover overlying the upper encapsulant layer.

43. The photovoltaic receiver of claim 42, wherein the cover comprises ethylenetetrafluroethyelene.

44. The photovoltaic receiver of claim 42, wherein a diode underlies the cover, and the cover includes a hole through which the diode protrudes.

45. The photovoltaic receiver of claim 42, wherein a diode underlies the cover and protrudes into a hole in the substrate.

46. The photovoltaic receiver of claim 42, wherein a filleted diode underlies the cover.

47. The photovoltaic concentrator module of claim 27, wherein the wired interconnection fits within the contour.

48. A method of making a photovoltaic receiver assembly, comprising the steps of:
a) providing a jig base having first and second faces;
b) providing a pin carrier comprising a plurality of alignment pins projecting from a face of the pin carrier;
c) causing the pin carrier to be positioned against the first face of the jig base so that the alignment pins project through corresponding holes of the jig base to project from the second face of the jig base;
d) positioning a first component of the photovoltaic receiver assembly against the second face of the jig base using the alignment pins to aid positioning;
e) clamping the first component to the second face of the jig base;
f) removing the pin carrier from the jig base;
g) positioning a second component of the photovoltaic receiver assembly against the first face of the jig base, wherein at least one of the first and second components is thermoformable; and
h) while the first and second components are held in the jig base, causing the components of the photovoltaic receiver assembly to be laminated together.

49. The method of claim 48, wherein the first component comprises a tabbed photovoltaic cell.

50. The method of claim 48, wherein the second component comprises a thermoformable film.

51. The method of claim 50, wherein said thermoformable film comprises ethylene vinyl acetate.

52. The method of claim 48, wherein step (d) further comprises positioning an additional component of the receiver assembly over the first component.

53. The method of claim 52, wherein said additional component comprises a dielectric film.

54. The method of claim 52, wherein said additional component comprises a dielectric film laminated to a substrate.

55. The method of claim 52, wherein said additional component comprises a dielectric film laminated to a contoured substrate, said contour corresponding to a wiring interconnection of the tabbed cell.

56. The method of claim 48, wherein step (g) further comprises positioning an additional component of the photovoltaic receiver assembly over the second component.

57. The method of claim 56, wherein said additional component is a film comprises ethylenetetrafluroethyelene.

58. The method of claim 48, wherein said clamping step comprises positioning a clamping board over the second face of the jig base in a manner such that the alignment pins fit into holes formed in the clamping board.

59. A method of making a photovoltaic receiver assembly, comprising the steps of:
a) providing a jig base having first and second faces;
b) positioning a first component of the photovoltaic receiver assembly against the second face of the jig base using a plurality of alignment features to aid positioning;
c) clamping the first component to the second face of the jig base;
d) positioning a second component of the photovoltaic receiver assembly against the first face of the jig base, wherein at least one of the first and second components is thermoformable; and
e) while the first and second components are held in the jig base, causing the components of the photovoltaic receiver assembly to be laminated together.

60. A method of making a photovoltaic receiver assembly, comprising the steps of:
a) arranging a plurality of components of the photovoltaic receiver assembly in a stack;
b) positioning a spacer adjacent a side of the stack; and
c) applying a laminating pressure to the stack and the spacer.

61. The method of claim 59, wherein step (b) comprises positioning a spacer on opposite sides of the stack and step (c) comprises applying laminating pressure to the stack and the spacers.
